(19) United States
(12) Patent Application Publication
(10) Pub. No.: US 2024/0318968 A1
(43) Pub. Date: Sep. 26, 2024

(54) METHODS AND SYSTEMS FOR PREDICTING AN ENERGY CONSUMPTION OF A VEHICLE FOR ITS TRAVEL ALONG A DEFINED ROUTE AND FOR ROUTING

(71) Applicant: BAREWAYS GMBH, Lübeck (DE)

(72) Inventors: Sascha KLEMENT, Lübeck (DE); Florian HARTMANN, Lübeck (DE)

(21) Appl. No.: 18/578,855

(22) PCT Filed: Aug. 3, 2022
(86) PCT No.: PCT/EP2022/071852

§ 371 Date: Jan. 12, 2024

(30) Foreign Application Priority Data
Aug. 3, 2021 (DE) 10 2021 120 212.4
Jul. 25, 2022 (DE) 10 2022 118 589.3

(51) Int. Cl. G01C 21/34; G06F 30/27

(52) U.S. Cl. CPC G01C 21/3469; G06F 30/27

(57) ABSTRACT

The invention relates to a method of predicting an energy consumption of a vehicle, particularly a battery electric vehicle (BEV) or hybrid electric vehicle (HEV), for its travel along a defined route between a given starting point and a given destination point. The method comprises obtaining, particularly calculating based on input data or receiving, respective values for a set of one or more energy consumption impact parameters of an energy consumption model for the vehicle. The set of energy consumption impact parameters represents in the energy consumption model one or more of the following impact factors on the energy consumption of the vehicle along the route: a surface impact factor (21) defining a road-surface-dependent impact on the energy consumption of the vehicle: a curvature impact factor (23) defining a road-curvature-dependent impact on the energy consumption of the vehicle: a wind impact factor (25), e.g., air-resistance factor, defining a wind-dependent impact on the energy consumption of the vehicle: a driving style impact factor (34) defining a driving style-dependent impact on the energy consumption of the vehicle; a tire pressure impact factor (31) defining a tire pressure-dependent impact for a selected driver on the energy consumption of the vehicle: a temperature-related battery consumption impact factor (32) defining an ambient temperature-dependent impact on the energy supply capability of a traction battery of the vehicle and/or on the power consumption, particularly for heating or cooling the battery, of an active cooling and/or heating system of the traction battery of the vehicle. The method further comprises determining a prediction for the energy consumption of the vehicle for the route based on the route, particularly its length, the energy consumption model, and the obtained one or more values of the set of energy consumption impact parameters.

The present invention relates to the field of vehicle technology, and particularly to the field of battery electric vehicles (BEV) or hybrid electric vehicles (HEV), i.e. vehicles the powertrain of which relies at least in parts on electrical energy provided by a battery. Specifically, the invention relates to a method and system for predicting an energy consumption of a vehicle for its travel along a defined route and for determining for a vehicle an optimal route between a starting point and a destination point.

Because the maximum amount of energy that can be provided by the battery and thus the range of the vehicle is per se limited, it is important for driver to know the energy consumption of the vehicle and particularly, specifically in connection with navigating a specific route, whether or not the current battery charge would be sufficient for traveling the whole route to a final destination. Particularly, range anxiety is a crucial issue for many customers with regards to electric vehicles. A reason for this so-called range anxiety is a driver's uncertainty about the remaining range the vehicle can drive with a certain level of battery power. This is not only because the range of electric vehicles depends on a larger number of factors compared to common vehicles with an internal combustion engine, but also because the network of charging stations is not (yet) as dense as that of gas stations, and most of the charging stations are located in urban areas or along highways. Apart from that, especially in rural areas, the range of an electric vehicle may be hard to predict as the range also highly depends, e.g., on road surfaces and conditions, elevation profiles and weather.

Therefore, it is in the interest of the driver to better understand whether or not a certain route can be driven without running out of battery power somewhere along the route without being able to recharge the battery. Thus, predicting the energy consumption of the vehicle for its travel along a defined route may be an important aspect in route planning.

Current methods of predicting the energy consumption of the vehicle, in particular a BEV or HEV largely depend on determining distances of sections along the route and an average power consumption rate of the vehicle at a maximum allowed speed per segment.

It is an object of the present invention to provide a method and a system for improving the prediction of the energy consumption of a vehicle for its travel along a defined route.

Specifically, it is desirable to improve one or more of efficiency, effectiveness, and accuracy of predicting the energy consumption of a vehicle for its travel along a defined route.

A solution to this problem is provided by the teaching of the independent claims. Various preferred embodiments of the present invention are provided by the teachings of the dependent claims.

A first aspect of the invention is directed to a method, particularly a computer-implemented method, of predicting an energy consumption of a vehicle, particularly a battery electric vehicle (BEV) or hybrid electric vehicle (HEV), for its travel along a defined route between a given starting point and a given destination point. The method comprises: (i) Obtaining, particularly calculating based on input data or receiving, respective values for a set of one or more energy consumption impact parameters of an energy consumption model for the vehicle, the set of energy consumption impact parameters representing in the energy consumption model one or more of the following impact factors on the energy consumption of the vehicle along the route:
a surface impact factor defining a road-surface-dependent impact on the energy consumption of the vehicle;
a curvature impact factor defining a road-curvature-dependent impact on the energy consumption of the vehicle;
a wind impact factor, e.g., air-resistance factor, defining a wind-dependent impact on the energy consumption of the vehicle;
a driving style impact factor defining a driving style-dependent impact on the energy consumption of the vehicle;
a tire pressure impact factor defining a tire pressure-dependent impact for a selected driver on the energy consumption of the vehicle;
a temperature-related battery consumption impact factor defining an ambient temperature-dependent impact on the energy supply capability of a traction battery of the vehicle and/or on the power consumption, particularly for heating or cooling the battery, of an active cooling and/or heating system of the traction battery of the vehicle; and

(ii) determining a prediction for the energy consumption of the vehicle for the route based on the route, particularly its length, the energy consumption model, and the obtained one or more values of the set of energy consumption impact parameters.

Accordingly, the determination of the energy consumption of the vehicle is based on an energy consumption model that relies on a set of one or more further impact factors, which have previously not been used for a prediction of an energy consumption or arrange based thereon. Since the energy consumption of the vehicle relates to the range of the vehicle, i.e. the distance the vehicle can drive with the present level of battery charge, the energy consumption model may be seen to provide a range prediction model. The method according to the first aspect of the invention thereby provides an improved way to use data such as live vehicle data, weather forecasts, or road quality information to predict the energy consumption and thereby the range of the vehicle, which may allow a customer to choose an appropriate route to arrive at a desired destination point.

The term “vehicle”, as used herein, refers particularly to an electric vehicle, including a battery electric vehicle (BEV) or hybrid electric vehicle (HEV). This may include any kind of vehicle, such as cars, trucks, vans, busses, tractors, or agricultural machines as well as e-bikes, e-scooters or the like. An electric vehicle particularly comprises an electric motor that drives the vehicle. The electric motor is powered by a battery, typically a rechargeable battery, which may be referred to as “electric vehicle battery” (“EVB”) or “traction battery”. The traction battery may be charged via a plug or any other power source, e.g., by means of hydrogen via a fuel cell.

The term “route”, as used herein, refers particularly to a connection between a start and a destination that can be travelled by the vehicle. The route may contain paved streets (from small roads to highways) but also unpaved paths, such as field paths or the like, or even no defined paths, e.g., fields, meadows, deserts, etc. as long as such rough terrains can be traveled by the vehicle. The route may contain intermediate points, particularly hand selected intermediate points between the starting point and destination point. It will be appreciated that any smallest route segment between two points (starting point, end point, and intermediate point(s)) may be considered a “route” between a starting point and an end point having no (hand selected) intermediate points.

The term “energy consumption model”, as used herein, refers particularly to a conceptual model of an energy consumption of a vehicle, particularly a computer implemented model that represents various factors that may have an impact on the energy consumption of the vehicle. As used herein, the energy consumption refers particularly to the energy consumption of an electric vehicle, such as a battery electric vehicle (BEV) or hybrid electric vehicle (HEV). As explained in more detail below, the energy consumption model relies on one or more energy consumption parameters that represent certain impact factors for the energy consumption of the vehicle. By executing the energy consumption model an energy consumption of the vehicle can be predicted particularly for a defined route between a starting point and a destination point.

The term “energy consumption impact parameter”, as used herein, refers particularly to a parameter of the energy consumption model that represents a certain “impact factor” (see below). The “energy consumption impact parameters” may particularly be assigned certain values that are suitable to be computed in the energy consumption model.

The term “impact factor”, as used herein, refers particularly to a factor or an aspect that has an impact on the energy consumption on the vehicle. More specifically, a factor that in some way has an influence on the energy consumption. The impact or influence may be either decreasing or increasing the energy consumption. However, although the term “impact factor” in general means that the respective factor may have an impact on the energy consumption, there may occur situations in which a certain factor may not change the energy consumption, e.g., when there is no wind.

The term “obtaining” data, e.g., values for a set of one or more energy consumption impact parameters of an energy consumption model for the vehicle, refers particularly to (i) calculating that data based on input data, derived e.g., by means of one or more sensors, or (ii) receiving that data from an external data source.

The terms “first”, “second”, “third” and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Where the term “comprising” or “including” is used in the present description and claims, it does not exclude other elements or steps. Where an indefinite or definite article is used when referring to a singular noun e.g., “a” or “an”, “the”, this includes a plural of that noun unless something else is specifically stated.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In the following, preferred embodiments of the method are described, which can be arbitrarily combined with each other or with other aspects of the present invention, unless such combination is explicitly excluded or technically impossible.

In some embodiments, the set of energy consumption impact parameters of the energy consumption model further comprises one or more of the following additional energy consumption impact parameters:
a mass impact factor defining a total vehicle mass-dependent impact on the energy consumption of the vehicle;
a temperature impact factor defining an ambient temperature-dependent impact on the energy consumption of the vehicle, particularly for autonomous or highly automated driving;
a route topology impact factor defining an elevation profile-dependent impact on the energy consumption of the vehicle, particularly for autonomous or highly automated driving.

In such embodiments, the obtaining, particularly calculating based on input data or receiving, the respective values for the set of energy consumption impact parameters comprises obtaining respective values for these one or more additional energy consumption impact parameters, and the determining a prediction for the energy consumption of the vehicle for the route is further based on the obtained one or more values of said additional energy consumption impact parameters.

Using such additional energy consumption impact parameters may further improve the prediction of the energy consumption of the vehicle and thereby a remaining range of the vehicle, particularly with respect to an accuracy of the prediction. Data as set forth above, including data on road condition, weather, and elevation profile as well as data relating to one or more of the other energy consumption impact parameters, may be used in the model, particularly by using static formulas or characteristics from real vehicles.

In some embodiments, one or more of the energy consumption impact parameters are each defined as a respective numerical parameter referring as a factor to a related pre-defined reference parameter. Using numerical parameters may facilitate computing the energy consumption model. Employing reference parameters may further facilitate the procedure. For instance, a reference surface impact parameter may relate to a factor of 1 for a reference road or standard road. Road surfaces that increase the energy consumption may then be associated with a factor greater than 1. Other roads that contribute to saving energy may be associated with a factor <1. It will be appreciated that other scales of factors and any suitable reference parameter may be implemented.

In some embodiments, the route is partitioned into a set of route segments. The obtaining, particularly calculating based on input data or receiving, respective values for a set of one or more energy consumption impact parameters may then comprise obtaining for at least one of said energy consumption impact parameters respective segment-specific values on a per route segment basis. Further, the determining a prediction for the energy consumption of the vehicle for the route may comprise calculating a respective segment-specific energy consumption of the vehicle for each of the route segments based on the obtained one or more values of the energy consumption impact parameters including said segment-specific values and integrating the calculated segment-specific energy consumptions to obtain the energy consumption of the vehicle for the whole route.

Partitioning the route into a set of route segments may further improve the prediction of the energy consumption of the vehicles. The various energy consumption impact parameters representing in the energy consumption model one or more of the following impact factors on the energy consumption of the vehicle along the route as set forth above may vary along the route. Thus, it may be advantageous, particularly for the accuracy of the prediction, to partition the route into route segments. More specifically, for each of the route segments a prediction for the energy consumption can be made, which may be more accurate than, e.g., using average values for the energy consumption parameters along the whole route.

In some embodiments, the method further comprises updating, particularly replacing or refining, one or more of the obtained values of the set of energy consumption impact parameters as a function of obtained consumption data representing a measured actual energy consumption and/or measured actual respective values for one or more of the energy consumption impact parameters of the set of energy consumption impact parameters for a travel of one or more reference vehicles, particularly the vehicle itself or an identical or comparable vehicle or fleet of several identical or comparable vehicles, along the route as a whole or said least one road segment thereof. Considering actually measured values (for the energy consumption itself or for one or more of the energy consumption parameters) may further improve the accuracy of the prediction of the energy consumption. In particular, the energy consumption prediction can be updated during the travel along the route, thereby getting more and more accurate over time the vehicle travels along the route.

In some related embodiments, the determining the prediction for the energy consumption of the vehicle for the route as a whole or said least one road segment thereof is further based on applying a machine-learning-based classifier to the consumption data and or the updated one or more values of the set of energy consumption impact parameters. Classification of the consumption data may be performed based on a consumption database. In this way, the prediction method can be further improved to provide more accurate results by training a machine learning classifier. Previous consumption predictions may thereby be used for improving the energy consumption prediction for future travels along a route.

In some of these embodiments, the method further comprises determining whether and if so, to what extent the consumption data has been impaired by traffic; and selectively using only such consumption data or components thereof as a basis for the updating of one or more of the values of the set of energy consumption impact parameters and/or as a basis for determining the prediction for the energy consumption of the vehicle for the route, for which consumption data or components thereof, respectively, no such impairment has been determined. Besides the aforementioned impact factors, traffic may play a role in the prediction of the energy consumption of a vehicle. For instance, the energy consumption of a vehicle may depend on how often the vehicle has to brake, stop, accelerate etc. It may be advantageous to eliminate those effects that come from traffic in the updating of the values. In other words, only those consumption data may be used for updating the values which is free of traffic influences, i.e. which represents the energy consumption of a vehicle that can drive without having to take care of other road users. This is particularly because traffic is an unpredictable or at least hardly predictable parameter. A machine learning classifier could be misled by traffic impaired data.

In some embodiments, the obtaining the respective values for a set of one or more energy consumption impact parameters of the energy consumption model for the vehicle, comprises one or more of the following:
pre-calculating and/or storing respective values for one or more of the surface impact factor, the curvature impact factor and the route topology factor either for the route as a whole or, if the route is partitioned into a set of route segments, for each of the route segments individually;
determining a respective value for the wind impact factor based on a respective linearly approximated wind direction determined for the route as a whole or for each of the route segments individually;
determining a respective value for the wind impact factor based on classifying the wind directions according to a discrete set of classes of different wind directions and the vehicle travel directions according to a discrete set of classes of different vehicle travel directions, and by obtaining the value for the wind impact factor through reading from a pre-defined data structure storing for each combination of a class of wind directions and a class of vehicle travel directions a respective pre-set value for the wind impact factor;
predicting, based on weather data relating to a geographical region through which the route leads, whether any significant wind or temperature-related impacts on the energy consumption of the vehicle are to be expected during its travel along the route, and using or ignoring one or more of the wind impact factor, the temperature-related battery consumption factor, and the temperature impact factor as a function of the result of said prediction;
representing the respective obtained value of at least two of the impact factors used for determining the prediction for the energy consumption of the vehicle for the route by a discrete value from a respective discrete set of allowed values, encoding the discrete values of said at least two impact factors to obtain a code representing all of the discrete values, and obtaining a value of the combined impact of said at least two impact factors on the energy consumption of the vehicle through reading from a pre-defined data structure storing for each possible variation of the code a respective pre-set value representing a combined impact of said at least two impact factors on the energy consumption of the vehicle.

Such embodiments may provide an effective way of reducing the necessary computing resources and may improve the efficiency of the method. In particular, rather than using exact values, one or more of the impact factors may be discretized and combined in a fingerprint/bit-field-like structure. In an exemplary embodiment, e.g., 18 bits could encode the current consumption situation and the dynamic impact could be retrieved from a lookup table having only 2∧18=262144 values. Such a lookup table can be pre-calculated and the whole impact calculation would require only one memory lookup. This could also be implemented in hardware for further runtime reduction. The discretization could also reduce the amount of to be transmitted data to a mobile device, i.e. not the raw weather data may be to be transmitted but only the reduced set (e.g., 3 bits for temperature and 3 bits for wind direction).

In some embodiments, the method further comprises updating the energy consumption model by adjusting it based on one or more of: a comparison of the energy consumption predicted for the route by means of the energy consumption model with a corresponding actually measured energy consumption acquired for the same vehicle or one or more comparable other vehicles along the route, and training data referring to so far uncovered geographical regions or unknown route conditions. Comparing the predicted energy consumption with corresponding energy consumption may improve the prediction. For instance, data for at least one of comparable regions, comparable vehicles, and comparable weather situations may be considered.

A second aspect of the present invention is directed to a routing method for determining for a vehicle an optimal route between a starting point and a destination point, the routing method comprising: (i) Predicting, according to the method of any one of the preceding claims, a respective energy consumption of the vehicle, particularly a battery electric vehicle (BEV) or hybrid electric vehicle (HEV), for each of a set of different possible routes between the starting point and the destination point; and (ii) Selecting or proposing, particularly using a network-based routing algorithm, an optimal route among the set of routes according to a defined optimization criterion as a function of the predicted respective energy consumptions of the vehicle for the different routes in the set of routes.

According to the routing method of the second aspect of the present invention, it is provided a method for determining a route between a starting point and a destination point that uses the aforementioned prediction of the energy consumption. In particular for electric vehicles (BEV or HEV), the energy consumption may be of interest for selecting or proposing an optimal route, while the energy consumption is not of such particular importance in route planning for common vehicles with an internal combustion engine that typically have a larger range or can at least travel in a well-equipped network of gas stations.

Particularly, the method of the second aspect may be implemented according to one or more of the following embodiments.

In some embodiments of the routing method of the second aspect, the optimization criterion is defined such that the route being selected as the optimal route from the set of routes is optimal in that it has the lowest predicted energy consumption. Selecting the route with the lowest predicted energy consumption may ensure that the route can be safely travelled without running out of battery. Apart from that, the route with the lowest energy consumption is a reasonable choice to optimize travel costs, and is also advantageous with respect to environmental aspects. In some embodiments, the routing method further comprises: predicting for the vehicle and each of the routes in the set of routes a respective travel time between the starting point and the destination point along the respective route; wherein the optimization criterion is defined such that the route being selected or proposed as the optimal route from the set of routes is optimal in that it has the lowest predicted travel time weighted by a factor reflecting the predicted energy consumption of the same route. Rather than a route with the lowest energy consumption, other users may prefer a route with the lowest predicted travel time to reach their destination earlier. Since the energy consumption of the vehicle and the travel time may depend on each other, it is advantageous to weight the travel time by a factor reflecting the predicted energy consumption. For instance, the energy consumption may be higher for a higher travel speed, and vice versa lower for a lower travel speed.

In some embodiments of the routing method of the second aspect the predicting a respective energy consumption of the vehicle for each of a set of different possible routes between the starting point and the destination point comprises predicting a respective energy consumption of the vehicle for each of said possible routes as a function of different energy consumption-related settings of the vehicle; and selecting or proposing an optimal route among the set of routes according to a defined optimization criterion comprises selecting or proposing, respectively, the optimal route as a function of both the predicted respective energy consumptions of the vehicle for the different routes in the set of routes and the different settings of the vehicle. The energy consumption of a vehicle may also depend on different settings of the vehicle, e.g., settings that control a drive mode or settings for the comfort of the passengers. Thus, it may be advantageous to provide an optimization criterion that considers not only the predicted energy consumption but also the different settings of the vehicle.

A third aspect of the present invention is directed to a method of determining a surface condition of a road, the method comprising:
(i) obtaining a reference value of an energy consumption of a vehicle, particularly a battery electric vehicle (BEV) or hybrid electric vehicle (HEV), for its travel along a defined route between a given starting point and a given destination point;
(ii) obtaining, particularly calculating based on input data or receiving, respective values for a set of one or more energy consumption impact parameters of an energy consumption model for the vehicle for its travel along the route, the set of energy consumption impact parameters representing in the energy consumption model one or more of the following impact factors on the energy consumption of the vehicle along the route:
   a curvature impact factor defining a road-curvature-dependent impact on the energy consumption of the vehicle;
   a wind impact factor defining a wind-dependent impact on the energy consumption of the vehicle;
   a driving style impact factor defining a driving style-dependent impact on the energy consumption of the vehicle;
   a tire pressure impact factor defining a tire pressure-dependent impact for a selected driver on the energy consumption of the vehicle;
   a temperature-related battery consumption impact factor defining an ambient temperature-dependent impact on the energy supply capability of a traction battery of the vehicle and/or on the power consumption of an active cooling and/or heating system of the traction battery of the vehicle;
   a mass impact factor defining a total vehicle mass-dependent impact on the energy consumption of the vehicle;
   a temperature impact factor defining an ambient temperature-dependent impact on the energy consumption of the vehicle;
   a route topology impact factor defining an elevation profile-dependent impact on the energy consumption of the vehicle;
(iii) estimating a value of a surface impact factor defining in the energy consumption model a road-surface-dependent impact on the energy consumption of the vehicle; and
(iv) determining a surface condition of a road based on the route, the energy consumption model, and the obtained one or more values of the set of energy consumption impact parameters.

According to the third aspect of the invention, a method can be provided which does not use the surface condition as a surface impact factor for the prediction of the energy consumption but vice versa determines the surface condition of a road using the energy consumption model in which the surface condition is not known. This determined parameter may then be used e.g., for other users and/or future energy consumption predictions.

A fourth aspect of the present invention is directed to a data processing system comprising means for carrying out the method of the first aspect and/or the method of the second aspect and/or the third aspect, in particular according to any one of the respective embodiments described herein.

A fifth aspect of the present invention is directed to a computer program or a computer program product comprising instructions which, when the program is executed by a computer or distributed computing system, cause the computer or distributed computing system, respectively, to carry out the method of the first aspect and/or the method of the second aspect and/or the third aspect, in particular according to any one of the respective embodiments described herein.

The computer program (product) may in particular be implemented in the form of a data carrier on which one or more programs for performing the method are stored. Preferably, this is a data carrier, such as a CD, a DVD or other optical medium, or a flash memory module. This may be advantageous, if the computer program product is meant to be traded as an individual product independent from the processor platform on which the one or more programs are to be executed. In another implementation, the computer program product is provided as a file on a data processing unit, in particular on a server, and can be downloaded via a data connection, e.g., the Internet or a dedicated data connection, such as a proprietary or local area network.

The system of the second aspect may accordingly have a program memory in which the computer program is stored. Alternatively, the system may also be set up to access a computer program available externally, for example on one or more servers or other data processing units, via a communication link, in particular to exchange with it data used during the course of the execution of the computer program or representing outputs of the computer program.

The explanations, embodiments and advantages described above in connection with the method of the first aspect similarly apply to the other aspects of the invention.

### BRIEF DESCRIPTION OF THE DRAWINGS

Further advantages, features and applications of the present invention are provided in the following detailed description and the appended drawings, wherein:

FIG. 1 schematically illustrates an exemplary embodiment of an energy consumption model;

FIG. 2 schematically illustrates an exemplary embodiment of a method of predicting an energy consumption;

FIG. 3 schematically illustrates an exemplary embodiment of a routing method; and

FIG. 4 schematically illustrates an exemplary embodiment of a method according to the present invention.

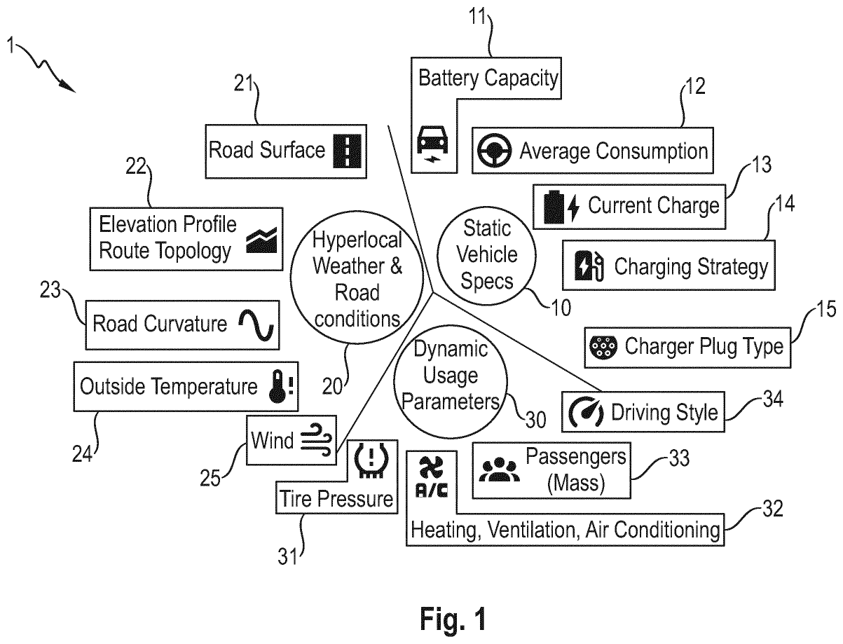

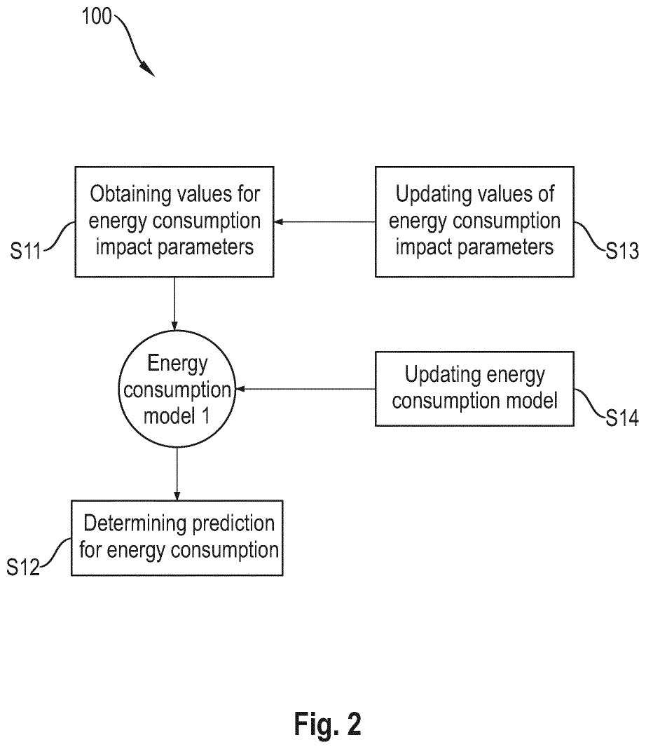

FIG. 1 shows an exemplary embodiment of an energy consumption model 1 that may be built as set forth below. The model 1 may then be applied to predict the range of a vehicle and to determine a most efficient route between a starting point and a destination point, using data such as live vehicle data, weather forecasts, and road quality information. An overview of such an overall process is described below, while exemplary embodiments of methods according to the present invention are then described with reference to FIGS. 2 to 4. It will be appreciated that the described energy consumption model 1 may be applied wherever appropriate. The same is valid for the given overview of phases 1 to 4 of an exemplary process, which likewise may be applied to any of the exemplary methods described in connection with FIGS. 2 to 4 wherever appropriate.

The energy consumption model 1 may comprise various energy consumption impact parameters that represent respective impact factors. The model considers different types of impact factors, which may be referred to as static vehicle specifications 10, hyperlocal weather and road conditions 20 and dynamic usage parameters 30. All of these different parameters somehow influence the energy consumption of a vehicle, in particular an electric vehicle, such as a battery electric vehicle (BEV) or hybrid electric vehicle (HEV). Values for the respective energy consumption parameters 10, 20, 30 may be obtained as described below. It will be appreciated that the parameters may be obtained in any suitable way, including reading out sensor data from the vehicle, receiving data from an external data source or manual input.

A battery capacity 11 may be obtained from the specifications of the vehicle. An average consumption 12 may be obtained from a dataset provided in the vehicle, e.g., derived from sensor data. Likewise, a current charge 13 may be obtained from such dataset. Apart from that, a charging strategy 14 may be considered, which may relate to user-defined levels up to which the battery shall be charged or discharged. A routing method may search for nearby charging stations to take into account the charging strategy, e.g., to avoid that the battery goes below a critical level. Also, a charger plug type 15 may be considered to find only fitting charging stations. Such data may be obtained e.g., from the OpenChargeMap. The charging strategy may further include further restrictions, such as personal preferences of a user, e.g., preference of the charging station at a home location, maximum price levels to consider or the preference of quick charging stations. For instance, charging at home or at subsidized charging stations may be much cheaper than at other locations. Manually selecting such route options is close to impossible. A charging strategy may also be important particularly because the network of charging stations is not (yet) as dense as that of gas stations, and most of the charging stations are in urban areas or along highways. And even if there is a dense network of charging stations, the driver might not want to spend half an hour to wait to continue.

Road conditions may have a large impact on the energy consumption of the vehicle. A road surface condition 21 may be obtained, for instance, from the road classification and road surface tag from OpenStreetMap. A topology of the route or elevation profile 22 may be obtained from a digital model, e.g., the SRTM Digital Elevation Model. The energy consumption increases for road segments going uphill, whereas a positive impact on the consumption may be achieved via recuperation when going downhill. A road curvature 23 may be calculated for every road segment or may be obtained from map data or vehicle sensors. With regards to weather conditions, an outside (ambient) temperature 24 may be obtained from weather data or from vehicle sensors. Likewise, wind data 25 may be obtained from weather data. Depending on the strength and direction of the wind, the energy consumption may increase or decrease.

The energy consumption of the vehicle may further depend on dynamic use parameters 30, i.e. parameters that may vary from trip to trip or even during a trip. A tire pressure 31 may be obtained from respective vehicle sensors. For instance, driving with a too low tire pressure may increase the energy consumption. Heating, ventilation, and air conditioning (HVAC) 32 may have a large impact on the energy consumption. In other words, the energy consumption of the vehicle is highly affected when a user turns on or off the heating or the air conditioning. The mass 33 of the vehicle may depend on the number of passengers, which may be obtained e.g., from respective seat sensors. Other aspects that have an impact on the mass of the vehicle, e.g., additional load or luggage, may be manually input or derived by sensor data. Also the driving style 34 has an impact on the energy consumption. It may be obtained from live vehicle data.

Having the described energy consumption model 1 of FIG. 1 in mind, it is now described by way of an example how the model 1 can be built and applied. It will be appreciated that the energy consumption model 1 may provide a range prediction model as the range of the vehicle depends on the energy consumption. The overview of the process described below is split up into four phases for the sake of better understanding. It may be advantageous to obtain some of the parameters for the whole trip, whereas other parameters are obtained for every road segment. In a phase 1, the energy consumption model is built. In particular, values for the energy consumption parameters are obtained as also described briefly above and described in more detail below.

In the example, an average vehicle consumption 12, a mass factor 33, a driving style factor 34 and a tire pressure factor 31 are determined for the whole trip. The average vehicle consumption 12 may be determined from the vehicle specification, the average consumption in the past, or the average consumption of comparable vehicles in a comparable geographic region. The mass factor 33 may define how much heavier the vehicle is than the standard vehicle in the vehicle specifications taking into account the number of passengers and additional load or luggage. This may be determined from manual input, average passenger weights (e.g., 75 kg) or from vehicle sensors, such as weight sensors, door open/close events. The driving style factor 34 may be determined from manual input or from measurements, e.g., “how often did the driver exceed speed limits in the past”, “how often was the determined power consumption exceeded”, “how often was recuperation used”, “how often did emergency brakes happen”, “how often were systems like ESP, ABS triggered”, or the like. The tire pressure factor 34 may represent for example how much lower is the tire pressure than the optimal value. This impact may be determined based on physical assumptions (e.g., 5% per bar below optimal pressure) or vehicle sensor measurements.

Using the aforementioned impact factors, a base consumption can be calculated, e.g., by multiplying the average vehicle consumption 12, mass factor 33, driving style factor 34 and tire pressure factor 31.

Continuing with obtaining values for the energy consumption impact parameters, certain impact factors may be determined for every road segment, such as a surface impact factor 21, a curvature impact factor 23, a wind impact factor 25, a temperature-related energy consumption impact factor 24, an impact of weather-related consumption profiles of heating, ventilation and air conditioning (HVAC) 32, and an elevation impact factor 22.

The surface impact factor 21 may be determined depending on the surface of the road. For instance, it may be determined how much more consumption is expected than on a smooth road (which may be assigned the value 1.0). The surface type may be derived from OpenStreetMap data, satellite imagery or vehicle sensor recordings from vehicles that have driven that same road or comparable roads in the same region. Typical values might be: paved, smooth roads=0.0; paved, rough roads=0.02; compacted roads=0.1; dirt roads=0.3; gravel roads=1.0; almost impassable roads=10.0.

The curvature impact factor 23 may particularly express that an energy consumption will be higher for a curvy road than for a straight road. The impact may be determined by deriving the road curvature from the road geometries of a map.

The wind impact factor 25 represents an impact of wind on the energy consumption. Head wind increases the required energy, while tailwind reduces the energy consumption. A relative wind impact may be determined from the vehicle orientation, the wind direction and the wind strength. This may be weighted with a factor obtained by manual input or by a vehicle specific air resistance/drag coefficients defined by the shape of the vehicle, taken e.g., from CAD data or the vehicle specifications. This may be relevant because the wind impact may depend on the shape of the vehicle. The aerodynamics of the vehicle have a major impact on the air resistance. This value may not even be constant for a vehicle, e.g., the bed of a typical US pickup truck may be open or closed or contain structures that increase the drag coefficient.

The temperature-related battery consumption impact factor 24 may be determined using static formulas or characteristics. The ambient temperature influences the consumption in terms of active battery heating or cooling, as well as (chemical) energy losses if below or above the sweet spot at around 23° C. A consumption increase may be assumed for temperatures above 23° C. in a range up to 35° C., and an even higher consumption increase for temperatures below 23° C. in a range down to −7° C. For instance, the temperature impact factor may be set to 5% for high temperatures and 10% for low temperatures. Characteristics of the vehicle or region/climate zone-specific battery characteristics may be considered.

The impact of weather-related consumption profiles of heating, ventilation and air conditioning (HVAC) 32 may be determined by obtaining weather data from a global weather prediction model. If the HVAC is active, a significant temperature dependent consumption increase can be assumed. Again, lower temperatures yield higher consumption, as it is more costly to heat cold air in the winter. Here, the HVAC influence factor can be set to 20% for high temperatures and 70% for low temperatures, for instance.

The elevation impact factor 22 can be determined based on maximum upward and downward slopes for each road segment. This data may be obtained from a digital elevation model (e.g., SRTM with a grid resolution of 30 m mapped to the road segment). Based on this information, an increased consumption can be assumed for going uphill, and gaining energy going downhill. As there are also other consumers in the vehicle that need to be powered next to the motor itself, the benefit of a negative slope may be set off with a threshold, that defines when recuperated energy comes effective.

A total consumption within a road segment can be obtained e.g., by multiplying the road segment length with the base consumption and all segment-related impact factors. Thus, a prediction for the energy consumption of a vehicle for its travel along said route can be made.

In a phase 2, the energy prediction can be used to find the most efficient route between the starting point and the destination point. When all or some of the above parameters are known the total energy consumption can be integrated as a cost factor into a routing algorithm and thus a route can be selected that is the most efficient or a combination of fastest and efficient (traded off with an efficiency factor). The routing algorithm may also return proposals how to save energy (e.g., using recuperation, showing the impact of HVAC or the personal driving style on consumption). Technically, this may be done by calculating the optimal route for a set of different settings (ensemble) and visualize the differences in consumption in relation to the current settings.

In this scenario, a challenge may be how to provide the dynamic data to the routing algorithm. Typically, a routing algorithm (e.g., bi-directional A*) will need to visit many edges of the routing graph and obtain their costs, wherein an edge of the routing graph may represent one road segment or a part of a road segment. Thus, a complex calculation of many impact factors would be difficult or even not be possible. As will be set forth below, some simplification steps may be implemented in a phase 2 to approximate the road specific impact factors without calculating the exact value as in phase 1.

The (almost) static impact factors (surface, curvature and elevation) may be pre-calculated and stored in advance for every road segment (this step needs to be performed only when the surface information is updated but generally remains constant). The wind direction may be calculated for the general road segment direction only (the vector from start to destination point) and not for every edge within a road segment. Thus, the number of wind direction lookups will significantly decrease.

A preprocessing step may be applied to first identify, if in the to be routed region any significant weather impact is expected. First, an area of interest may be defined, e.g., regions where the route will most likely be. This may be for instance a rectangle, circle or ellipse larger to some amount than the distance between starting point and destination point with the center between starting and destination points. Then, it may be assessed if any relevant temperature (more than x degrees higher/lower than the temperature sweet spot) are in this region. Further, it may be assessed if the wind strength within this region is above a certain threshold. If neither temperature nor wind strength are above the thresholds the dynamic impact factors for this routing request may be set to a fixed value of 1. Thus, no weather lookups would be made and the request would be significantly faster.

Obtaining the wind direction usually requires evaluating trigonometric functions which is typically slow (slower than simple math). Therefore, the wind direction and the vehicle direction may be classified into a discrete set of directions (e.g., 8 or 16 discrete directions; e.g., north=0, north-east=1 and so on) and substitute the trigonometric functions with a matrix lookup (e.g., vehicle direction north=0 and wind direction south=4 would deliver a value of 1 indicating the maximum impact).

All these steps can of course be also applied in phase 1, however, it is most critical when the cost function of the routing algorithm needs to be evaluated thousands and millions of times.

In yet another optimization step, all impact factors may be discretized and combined in fingerprint/bit-field-like structure, e.g., 3 bits encode 8 different road surface impact classes, 3 bits encode 8 vehicle directions, 3 bits encode 8 wind directions, 2 bits encode 4 wind strengths, 3 bits encode 8 temperature, 4 bits encode 8 slope values (e.g., one bit for upward/downward and 3 bits to encode the amount of slope). Thus, 18 bits would encode the current consumption situation and the dynamic impact could be retrieved from a lookup table having only 2∧18=262144 values. This lookup table can be pre-calculated and the whole impact calculation would require only one memory lookup.

The above optimization steps could also be implemented in hardware for further runtime reduction. The discretization could also reduce the amount of to be transmitted data to a mobile device, i.e. not the raw weather data is to be transmitted but only the reduced set (e.g., 3 bits for temperature and 3 bits for wind direction).

In a phase 3, live vehicle data may be used to obtain more accurate energy consumption estimates (consumption profiles) for every road segment. For this purpose, live consumption recording may be performed in the electric vehicle or in a vehicle fleet. Consumption values and related dynamic data (elevation, weather, driving style, tire pressures, vehicle configuration) may be stored for that location, data and time in a database.

Then, a machine learning classifier can be trained to predict road-segment-specific consumption based on the consumption database (the above simplification steps may likewise be applied). For every routing request, range prediction or consumption prediction the classifier may be assessed to obtain a consumption estimate from comparable regions, comparable vehicles, or comparable weather situations.

It may be preferred to record data only if no traffic impact is known (as this is an unpredictable parameter and may mislead the classifier). Other filter methods may be applied alternatively or in addition to avoid unrealistic consumption predictions. Based on machine learning-based predictor the static and dynamic formulas from phase 1 may then be adjusted.

In a phase 4, live consumption values may be compared with consumption predictions (i) to continuously update the prediction model or (ii) to derive estimates for the road surface impact. The energy consumption prediction model may be continuously updated, e.g., if consumption prediction is too far off. The model may also be trained again with data from so far uncovered regions or unknown conditions. The comparison may further be made to derive estimates for road surface impact. If all other values are available but no road surface information (this is actually the most difficult to obtain as it may change over time and manually assessment may be prone to errors) the road surface impact may be derived from the consumption information. Strictly speaking, it may not be derived the type of surface but its impact on the energy consumption. Generally, this could be used to fill gaps in the basemap for road segments where no road surface or road condition data is available by default.

If all values are available, it may also be envisioned to derive degradation of roads, particularly the road surface if the consumption increases consistently over time. This will require continuously monitoring the consumption trend for each road segment, i.e. a deviation from the predicted consumption may be stored for a passage of a road segment, and trends may be analyzed.

Referring now to FIG. 2, an exemplary embodiment of a method according to the first aspect of the invention is described. More specifically, FIG. 2 illustrates an exemplary method 100 of predicting an energy consumption of a vehicle. The method 100 may basically comprise the steps as explained above with respect to phase 1.

In a first step S11, values for the energy consumption parameters are obtained. These parameters may reflect one or more or all of the aforementioned impact parameters illustrated in FIG. 1. They may be obtained as described above with respect to phase 1 of the overall process. The obtained values for the energy consumption parameters are the input data for the energy consumption model 1 as described above. In a further step S12, a prediction for the energy consumption of the vehicle may then be made based on a route, the energy consumption model 1 along with the obtained values of the set of energy consumption parameters.

A further step S13 of updating the values of the energy consumption parameters may be performed. The updated values may then be used to evaluate the energy consumption model 1. Updating may be performed by using live vehicle data as described above with respect to phase 3 of the overall process. More specifically, at least one of a measured actual energy consumption and measured actual values for the respective energy consumption impact parameters may replace the previous values or may at least refine those values. In this way, more accurate consumption estimates (predictions) can be made.

It may further be implemented a step S14 of updating the energy consumption model 1 as described above with respect to phase 4(i). This may be done by comparing the predicted energy consumption with an actually measured energy consumption, which had been measured for the same vehicle on that route or one or more comparable vehicles for that route. The updating of the energy consumption model 1 may also include a training of the energy consumption model with data from so far uncovered geographical regions or route conditions.

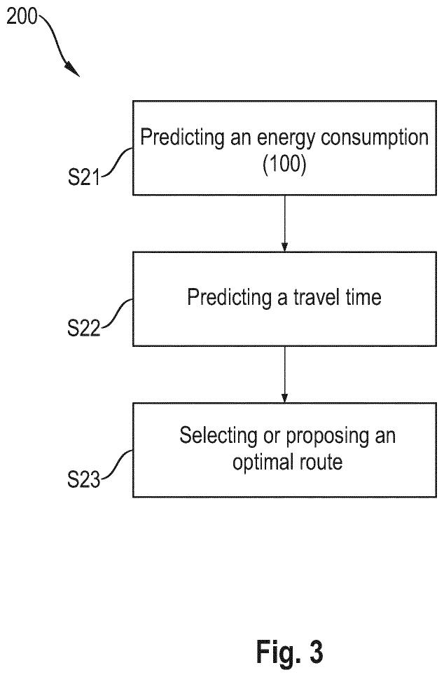

Referring now to FIG. 3, an exemplary embodiment of a method according to the second aspect of the invention is described. More specifically, FIG. 3 illustrates an exemplary routing method 200 for determining for a vehicle an optimal route between a starting point and a destination point. The method 200 may basically comprise the steps as explained above with respect to phase 2.

In a first step S21, an energy consumption of the vehicle may be predicted according to the above-described method 100. In particular, an energy consumption may be predicted for each of a set of different possible routes between the starting point and the destination point. In a step 23, an optimal route among the set of routes may be selected or proposed. This may be done using a defined optimization criterion, e.g., the route with the lowest predicted energy consumption. The method 200 may include a further step S22 of predicting a travel time for each of the set of routes. The travel time may then also be used as an optimization criterion, e.g., for selecting or proposing the route with the lowest predicted travel time.

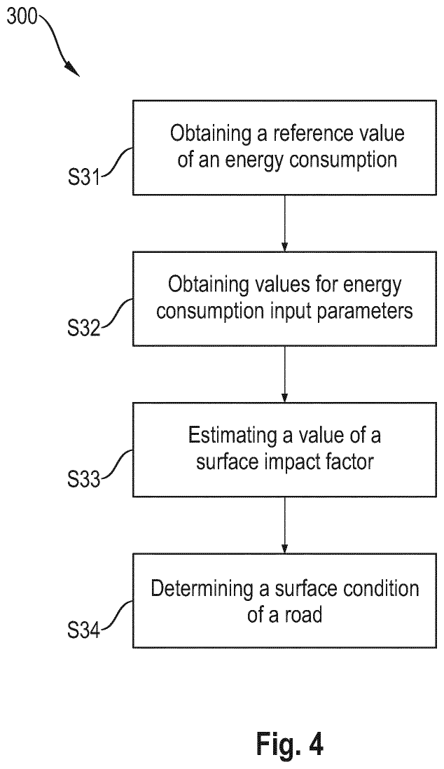

Referring now to FIG. 4, an exemplary embodiment of a method according to the third aspect of the invention is described. More specifically, FIG. 4 illustrates an exemplary method 300 of determining a surface condition of a road. The method 300 may basically comprise the steps as explained above with respect to phase 4(ii).

As described above in phase 4(ii) of the overall process, it may be envisioned to obtain information about the road surface if no value for the surface impact parameter 21 is available. In a first step S31, a reference value of an energy consumption for a vehicle for its travel along a defined route may be obtained. In a step S32, values for the aforementioned energy consumption parameters except for the surface impact parameters may be obtained as described above with respect to phase 1. Then, in a step S33, a value for the surface impact parameter 21 may be estimated. Based on this estimated surface impact parameter, the energy consumption model 1 and the obtained values for the other energy consumption impact parameters, a surface condition of the road may then be determined in a step S34. While above some exemplary embodiments of the present invention have been described, it has to be noted that a great number of variations thereto exists. Furthermore, it is appreciated that the described exemplary embodiments only illustrate non-limiting examples of how the present invention can be implemented and that it is not intended to limit the scope, the application or the configuration of the herein-described apparatuses and methods. Rather, the preceding description will provide the person skilled in the art with constructions for implementing at least one exemplary embodiment of the invention, wherein it has to be understood that various changes of functionality and the arrangement of the elements of the exemplary embodiment can be made, without deviating from the subject-matter defined by the appended claims and their legal equivalents.

### LIST OF REFERENCE SIGNS

1 energy consumption model
10 static vehicle specifications
11 battery capacity
12 average consumption
13 current charge
14 charging strategy
15 charger plug type
20 hyperlocal weather and road conditions
21 surface impact factor
22 route topology impact factor
23 curvature impact factor
24 temperature impact factor
25 wind impact factor
30 dynamic usage parameters
31 tire pressure impact factor
32 HVAC impact factor
33 mass impact factor
34 driving style impact factor
100 exemplary embodiment of a method of predicting an energy consumption of a vehicle
200 exemplary embodiment of a routing method for determining for a vehicle an optimal route between a starting point and a destination point
300 exemplary embodiment of a method of determining a surface condition of a road

What is claimed is:

1. A method of predicting an energy consumption of a vehicle for its travel along a defined route between a given starting point and a given destination point, the method comprising:
Obtaining respective values for a set of one or more energy consumption impact parameters of an energy consumption model (for the vehicle, the set of energy consumption impact parameters representing in the energy consumption model one or more of the following impact factors on the energy consumption of the vehicle along the route:
a surface impact factor defining a road-surface-dependent impact on the energy consumption of the vehicle;
a curvature impact factor defining a road-curvature-dependent impact on the energy consumption of the vehicle;
a wind impact factor defining a wind-dependent impact on the energy consumption of the vehicle;
a driving style impact factor defining a driving style-dependent impact on the energy consumption of the vehicle;
a tire pressure impact factor defining a tire pressure-dependent impact for a selected driver on the energy consumption of the vehicle;
a temperature-related battery consumption impact factor defining an ambient temperature-dependent impact on the energy supply capability of a traction battery of the vehicle and/or on the power consumption of an active cooling and/or heating system of the traction battery of the vehicle;
determining a prediction for the energy consumption of the vehicle for the route based on the route the energy consumption model, and the obtained one or more values of the set of energy consumption impact parameters.

2. The method of claim 1, wherein:
the set of energy consumption impact parameters of the energy consumption model further comprises one or more of the following additional energy consumption impact parameters:
a mass impact factor defining a total vehicle mass-dependent impact on the energy consumption of the vehicle;
a temperature impact factor defining an ambient temperature-dependent impact on the energy consumption of the vehicle;
a route topology impact factor defining an elevation profile-dependent impact on the energy consumption of the vehicle;
obtaining the respective values for the set of energy consumption impact parameters comprises obtaining respective values for these one or more additional energy consumption impact parameters; and
determining a prediction for the energy consumption of the vehicle for the route is further based on the obtained one or more values of said additional energy consumption impact parameters.

3. The method of claim 1, wherein one or more of the energy consumption impact parameters are each defined as a respective numerical parameter referring as a factor to a related pre-defined reference parameter.

4. The method of claim 1, wherein:
the route is partitioned into a set of route segments;
obtaining respective values for a set of one or more energy consumption impact parameters comprises obtaining for at least one of said energy consumption impact parameters respective segment-specific values on a per route segment basis; and determining a prediction for the energy consumption of the vehicle for the route comprises calculating a respective segment-specific energy consumption of the vehicle for each of the route segments based on the obtained one or more values of the energy consumption impact parameters including said segment-specific values and integrating the calculated segment-specific energy consumptions to obtain the energy consumption of the vehicle for the whole route.

5. The method of claim 1, further comprising updating one or more of the obtained values of the set of energy consumption impact parameters as a function of obtained consumption data representing a measured actual energy consumption and/or measured actual respective values for one or more of the energy consumption impact parameters of the set of energy consumption impact parameters for a travel of one or more reference vehicles along the route as a whole or said least one road segment thereof.

6. The method of claim 5, wherein determining the prediction for the energy consumption of the vehicle for the route as a whole or said least one road segment thereof is further based on applying a machine-learning-based classifier to the consumption data and or the updated one or more values of the set of energy consumption impact parameters.

7. The method of claim 5, further comprising:
determining whether and if so, to what extent the consumption data has been impaired by traffic; and
selectively using only such consumption data or components thereof as a basis for the updating of one or more of the values of the set of energy consumption impact parameters and/or as a basis for determining the prediction for the energy consumption of the vehicle for the route, for which consumption data or components thereof, respectively, no such impairment has been determined.

8. The method of claim 1, wherein obtaining the respective values for a set of one or more energy consumption impact parameters of the energy consumption model for the vehicle comprises one or more of the following:
pre-calculating and/or storing respective values for one or more of the surface impact factor, the curvature impact factor and the route topology factor either for the route as a whole or, if the route is partitioned into a set of route segments, for each of the route segments individually;
determining a respective value for the wind impact factor based on a respective linearly approximated wind direction determined for the route as a whole or for each of the route segments individually;
determining a respective value for the wind impact factor based on classifying the wind directions according to a discrete set of classes of different wind directions and the vehicle travel directions according to a discrete set of classes of different vehicle travel directions, and by obtaining the value for the wind impact factor through reading from a pre-defined data structure storing for each combination of a class of wind directions and a class of vehicle travel directions a respective pre-set value for the wind impact factor;
predicting, based on weather data relating to a geographical region through which the route leads, whether any significant wind or temperature-related impacts on the energy consumption of the vehicle are to be expected during its travel along the route, and using or ignoring one or more of the wind impact factor, the temperature-related battery consumption factor, and the temperature impact factor as a function of the result of said prediction;
representing the respective obtained value of at least two of the impact factors used for determining the prediction for the energy consumption of the vehicle for the route by a discrete value from a respective discrete set of allowed values, encoding the discrete values of said at least two impact factors to obtain a code representing all of the discrete values, and obtaining a value of the combined impact of said at least two impact factors on the energy consumption of the vehicle through reading from a pre-defined data structure storing for each possible variation of the code a respective pre-set value representing a combined impact of said at least two impact factors on the energy consumption of the vehicle.

9. The method of claim 1, further comprising updating the energy consumption model by adjusting it based on one or more of:
a comparison of the energy consumption predicted for the route by means of the energy consumption model with a corresponding actually measured energy consumption acquired for the same vehicle or one or more comparable other vehicles along the route; and
training data referring to so far uncovered geographical regions or unknown route conditions.

10. A routing method for determining for a vehicle an optimal route between a starting point and a destination point, the routing method comprising:
predicting, according to the method of claim 1, a respective energy consumption of the vehicle for each of a set of different possible routes between the starting point and the destination point; and
selecting or proposing an optimal route among the set of routes according to a defined optimization criterion as a function of the predicted respective energy consumptions of the vehicle for the different routes in the set of routes.

11. The routing method of claim 10, wherein the optimization criterion is defined such that the route being selected as the optimal route from the set of routes is optimal in that it has the lowest predicted energy consumption.

12. The routing method of claim 10, further comprising:
predicting for the vehicle and each of the routes in the set of routes a respective travel time between the starting point and the destination point along the respective route;
wherein the optimization criterion is defined such that the route being selected or proposed as the optimal route from the set of routes is optimal in that it has the lowest predicted travel time weighted by a factor reflecting the predicted energy consumption of the same route.

13. The routing method of claim 10, wherein
predicting a respective energy consumption of the vehicle for each of a set of different possible routes between the starting point and the destination point comprises predicting a respective energy consumption of the vehicle for each of said possible routes as a function of different energy consumption-related settings of the vehicle; and
selecting or proposing an optimal route among the set of routes according to a defined optimization criterion comprises selecting or proposing, respectively, the optimal route as a function of both the predicted respective energy consumptions of the vehicle for the different routes in the set of routes and the different settings of the vehicle.

14. A method of determining a surface condition of a road, the method comprising:
obtaining a reference value of an energy consumption of a vehicle for its travel along a defined route between a given starting point and a given destination point;
obtaining respective values for a set of one or more energy consumption impact parameters of an energy consumption model for the vehicle for its travel along the route, the set of energy consumption impact parameters representing in the energy consumption model one or more of the following impact factors on the energy consumption of the vehicle along the route:
a curvature impact factor defining a road-curvature-dependent impact on the energy consumption of the vehicle;
a wind impact factor defining a wind-dependent impact on the energy consumption of the vehicle;
a driving style impact factor defining a driving style-dependent impact on the energy consumption of the vehicle;
a tire pressure impact factor defining a tire pressure-dependent impact for a selected driver on the energy consumption of the vehicle;
a temperature-related battery consumption impact factor defining an ambient temperature-dependent impact on the energy supply capability of a traction battery of the vehicle and/or on the power consumption of an active cooling and/or heating system of the traction battery of the vehicle;
a mass impact factor defining a total vehicle mass-dependent impact on the energy consumption of the vehicle;
a temperature impact factor defining an ambient temperature-dependent impact on the energy consumption of the vehicle;
a route topology impact factor defining an elevation profile-dependent impact on the energy consumption of the vehicle;
estimating a value of a surface impact factor defining in the energy consumption model a road-surface-dependent impact on the energy consumption of the vehicle; and
determining a surface condition of a road based on the route, the energy consumption model, and the obtained one or more values of the set of energy consumption impact parameters.

15. (canceled)

16. (canceled)

17. The method of claim 2, wherein one or more of the energy consumption impact parameters are each defined as a respective numerical parameter referring as a factor to a related pre-defined reference parameter.

18. The method of claim 2, wherein:
the route is partitioned into a set of route segments;
obtaining respective values for a set of one or more energy consumption impact parameters comprises obtaining for at least one of said energy consumption impact parameters respective segment-specific values on a per route segment basis; and
determining a prediction for the energy consumption of the vehicle for the route comprises calculating a respective segment-specific energy consumption of the vehicle for each of the route segments based on the obtained one or more values of the energy consumption impact parameters including said segment-specific values and integrating the calculated segment-specific energy consumptions to obtain the energy consumption of the vehicle for the whole route.

19. The method of claim 2, further comprising updating one or more of the obtained values of the set of energy consumption impact parameters as a function of obtained consumption data representing a measured actual energy consumption and/or measured actual respective values for one or more of the energy consumption impact parameters of the set of energy consumption impact parameters for a travel of one or more reference vehicles along the route as a whole or said least one road segment thereof.

20. The method of claim 6, further comprising:
determining whether and if so, to what extent the consumption data has been impaired by traffic; and
selectively using only such consumption data or components thereof as a basis for the updating of one or more of the values of the set of energy consumption impact parameters and/or as a basis for determining the prediction for the energy consumption of the vehicle for the route, for which consumption data or components thereof, respectively, no such impairment has been determined.

21. The method of claim 2, wherein obtaining the respective values for a set of one or more energy consumption impact parameters of the energy consumption model for the vehicle comprises one or more of the following:
pre-calculating and/or storing respective values for one or more of the surface impact factor, the curvature impact factor and the route topology factor either for the route as a whole or, if the route is partitioned into a set of route segments, for each of the route segments individually;
determining a respective value for the wind impact factor based on a respective linearly approximated wind direction determined for the route as a whole or for each of the route segments individually;
determining a respective value for the wind impact factor based on classifying the wind directions according to a discrete set of classes of different wind directions and the vehicle travel directions according to a discrete set of classes of different vehicle travel directions, and by obtaining the value for the wind impact factor through reading from a pre-defined data structure storing for each combination of a class of wind directions and a class of vehicle travel directions a respective pre-set value for the wind impact factor;
predicting, based on weather data relating to a geographical region through which the route leads, whether any significant wind or temperature-related impacts on the energy consumption of the vehicle are to be expected during its travel along the route, and using or ignoring one or more of the wind impact factor, the temperature-related battery consumption factor, and the temperature impact factor as a function of the result of said prediction;
representing the respective obtained value of at least two of the impact factors used for determining the prediction for the energy consumption of the vehicle for the route by a discrete value from a respective discrete set of allowed values, encoding the discrete values of said at least two impact factors to obtain a code representing all of the discrete values, and obtaining a value of the combined impact of said at least two impact factors on the energy consumption of the vehicle through reading from a pre-defined data structure storing for each possible variation of the code a respective pre-set value representing a combined impact of said at least two impact factors on the energy consumption of the vehicle.

22. The method of claim 2, further comprising updating the energy consumption model by adjusting it based on one or more of:
a comparison of the energy consumption predicted for the route by means of the energy consumption model with a corresponding actually measured energy consumption acquired for the same vehicle or one or more comparable other vehicles along the route; and
training data referring to so far uncovered geographical regions or unknown route conditions.
